(19) United States
(12) Patent Application Publication
(10) Pub. No.: US 2002/0061649 A1
(43) Pub. Date: May 23, 2002

(54) Ashing method

(76) Inventor: Takanobu Nishida, Fukuyama-shi (JP)

Correspondence Address: NIXON & VANDERHYE P.C., 8th Floor, 1100 North Glebe Road, Arlington, VA, 22201, US

(21) Appl. No.: 09/986,987

(22) Filed: Nov. 13, 2001

(30) Foreign Application Priority Data
Nov. 15, 2000 (JP) 2000-348477

(51) Int. Cl. H01L 21/302; H01L 21/461

(52) U.S. Cl. 438/689

(57) ABSTRACT

An ashing method comprises the steps of: holding a substrate having a resist mask formed through an insulating film in a chamber of an ashing apparatus; and applying an RF electric power to activate an oxygen-containing gas introduced in the chamber in order to perform ashing of the resist mask, while an RF electric power is applied to the substrate.

### CROSS-REFERENCE TO RELATED APPLICATION

This application is related to Japanese application No. 2000-348477 filed on Nov. 15, 2000, whose priority is claimed under 35 USC § 119, the disclosure of which is incorporated by reference in its entirety.

### BACKGROUND OF THE INVENTION

1. Field of the Invention

The present invention relates to an ashing method, and more particularly to an ashing method in which when a resist formed through a low dielectric constant film as an interlayer insulating film is subjected to ashing, the change in the film quality of the interlayer insulating film can be reduced.

2. Description of the Related Art

As a semiconductor device becomes minute in recent years, capacitance between wiring lines in the semiconductor device is increased, and a signal delay by this becomes an important problem.

As a method of reducing the capacitance between the wiring lines, for example, there is a method in which a low dielectric constant film is adopted as an interlayer insulating film used between wiring layers.

However, the film quality of the low dielectric constant film is apt to change when it is exposed to plasma of ashing or the like. In the case where a resist pattern formed to perform a hole etching or the like on an interlayer insulating film made of a low dielectric constant film is removed by an ashing, Si—H bonding or Si—CH₃ bonding in the film as a source to reduce the dielectric constant of the interlayer insulating film is cut during the ashing, and Si—OH bonding is generated at that portion. By such change in the film quality, the dielectric constant is raised, and the hole resistance is raised, and further, an increase in wiring capacitance and a signal delay are caused, thereby deteriorating the performance of the device.

Then, there are various methods for suppressing the increase of the dielectric constant due to the ashing treatment in the interlayer insulating film.

For example, Japanese Patent Laid-Open No. 2000-77410 proposes a method in which a pressure in the ashing is controlled to be within a suitable range and an ashing mainly using ions is performed in a single wafer processing type ashing apparatus, in the case where a resist mask formed on a low dielectric constant film is removed by ashing.

Besides, Japanese Patent Laid-Open No. 87332/1999 proposes a method in which even if Si—H bonding or Si—CH₃ bonding is cut during an O₂ ashing, it is successively exposed to H₂ plasma, so that the cut Si—H bonding is restored.

However, in the ashing mainly using pressure control, since there is an upper limit in ionization energy control, there is a case where necessary ionization energy can not be obtained by the pressure control, and according to the kind of the low dielectric constant film, there is a case where the increase of the dielectric constant can not be sufficiently suppressed.

Besides, in the method of exposure to the H₂ plasma after the O₂ ashing, since the step of exposure to the H₂ plasma is added, a treatment time is prolonged, and manufacturing cost is increased.

### SUMMARY OF THE INVENTION

The present invention has been made in view of the above problems, and an object of the invention is to provide an ashing method in which an increase of dielectric constant of a low dielectric constant film can be efficiently suppressed without causing an increase of manufacturing cost.

The present invention provides an ashing method comprising the steps of: holding a substrate having a resist mask formed through an insulating film in a chamber of an ashing apparatus; and

applying an RF electric power to activate an oxygen-containing gas introduced in the chamber in order to perform ashing of the resist mask, while an RF electric power is applied to the substrate.

### BRIEF DESCRIPTION OF THE DRAWINGS

FIG. 1 is a schematic sectional view of a main portion of an ashing apparatus used for an ashing method of the invention.

FIG. 2 is a view showing FT-IR waveforms of an interlayer insulating film before and after the ashing method of the invention.

FIG. 3 is a graph showing a change in dielectric constant of an interlayer insulating film in the case where bias power is changed in the ashing method of the invention.

FIG. 4 is a view showing FT-IR waveforms of an interlayer insulating film in the case where a resist is subjected to ashing without applying bias power.

FIG. 5 is a schematic sectional view of a main portion of an ashing apparatus used for a conventional ashing method.

FIG. 6 is a view showing FT-IR waveforms of an interlayer insulating film before and after ashing is performed by using the conventional ashing apparatus.

### DETAILED DESCRIPTION OF THE PREFERRED EMBODIMENTS

An ashing method of the present invention is a method which is performed for removing a resist mask formed on a substrate through at least an insulating film.

As a substrate used in the method of the invention, all substrates normally used for manufacturing semiconductor devices can be listed, and a glass substrate, a plastic substrate, a semiconductor substrate, a semiconductor wafer and the like can be enumerated. Specifically, various substrates such as an element semiconductor (silicon, germanium, etc.) substrate, a compound semiconductor (GaAs, ZnSe, silicon germanium, etc.) substrate, a substrate of SOI, SOS or the like, an element semiconductor wafer (silicon, etc.), a quartz substrate, a plastic (polyethylene, polystylene, polyimide, etc.) substrate and the like can be enumerated. Incidentally, an element such as a transistor, a capacitor or a resistor, a circuit including these, an interlayer insulating film, a wiring layer and the like may be formed on the substrate.

As an insulating film formed on the substrate, what are normally formed as interlayer insulating films can be enumerated, and especially, a low dielectric constant film is preferable. Here, the low dielectric constant film is a film having a dielectric constant of, for example, about 3.5 or less. For example, a silicon nitride film; or an SiO₂ film, films containing Si, O and F, films containing Si, O and C or films containing C and F formed by a CVD method; inorganic HSQ (hydrogen silsesquioxane) films, MSQ (methly silsesquioxane) films, PAE (polyarylene ether) films, BCB films, porous films; or films containing C and F formed by coating or the like can be enumerated. The thickness of the insulating film is not particularly limited, and a thickness of about 4000 to 10000 Å can be given as an example.

The resist mask includes all formed of resist normally used in the field of a semiconductor process, and for example, masks of various resists, such as negative type resist (cyclized cis-1, 4-polyisoprene, polyvinyl cinnamate, etc.), positive type resist (novolak system) for an electron beam or X rays; far-ultraviolet (deep-UV) resist (polymethyl metacrylate, t-Boc system); and resist for an ion beam, can be enumerated. Specifically, acetal resist (TDUR-P015), aniling (TMX-1191Y), hybrid resist (SPR550) and the like can be enumerated. The thickness of the resist mask is not particularly limited, and for example, a thickness of about 7000 to 9000 Å can be given as an example.

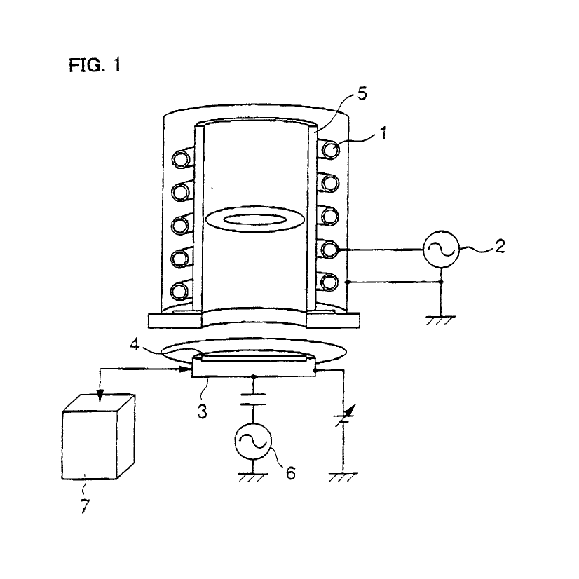

An ashing apparatus which can be used for the present invention is not particularly limited as long as it has been commonly used. As long as RF power can be applied to make an introduced gas active or preferably plasma, and RF power can be applied to a substrate to be etched, ashing apparatuses of various shapes and principles, such as a cylindrical type, a parallel flat plate type, a hexode type, an effective magnetic field RIE type, an effective magnetic field microwave type, a microwave type and an ECR type, can be enumerated. Specifically, as shown in FIG. 1, an ashing apparatus is given as an example, which includes at least a vacuum chamber, a lower electrode formed at a lower position in the vacuum chamber, a power source capable of applying RF electric power for activating a gas at the side of the vacuum chamber and a power source capable of applying RF electric power to a substrate. Incidentally, in such an apparatus, an upper electrode may be formed at an outer circumference of the vacuum chamber, or a coil (electromagnetic coil, etc.) for plasma generation may be arranged. It is preferable that the power source capable of applying the RF electric power for activating the gas is connected to only the vacuum chamber or the vacuum chamber and the upper electrode or the coil or the like. Besides, it is preferable that the lower electrode is provided with a mechanism for holding the substrate, and further, it is preferable that the lower electrode is provided with a mechanism for controlling the temperature of the substrate. It is preferable that the power source capable of applying the RF electric power to the substrate is connected to the lower electrode.

In the ashing method of the invention, normally, an oxygen-containing gas is introduced into the chamber, and the RF electric power is applied to the chamber or the like to activate the gas, for example, to transform the gas into plasma. As the introduced oxygen-containing gas, as long as it does not exert a bad influence on the film quality or the like of the insulating film (low dielectric constant film) formed on the substrate, the gas may be an almost pure oxygen gas, an ozone gas, a mixture thereof, or a mixture of either or both of these gases with a gas such as N₂ gas or CF₄ gas. It is appropriate that the oxygen-containing gas is introduced at, for example, about 50 to 500 SCCM, or 100 to 250 SCCM.

Although the RF electric power applied to activate the gas introduced in the chamber is not particularly limited, in view of the kind, amount, speed and the like of the foregoing introduced gas, it is appropriate that the RF electric power is about 1000 W or less, for example, in the range of about 100 to 1000 W.

Besides, the RF electric power applied to the side of the substrate is preferably applied to the substrate through the lower electrode for holding the substrate, and in view of the kind, amount, speed of the foregoing introduced gas, the applied RF electric power for activating the gas introduced in the chamber and the like, it is appropriate that the RF electric power is about 150 W or higher, about 200 W or higher, about 250 W or higher, or in the range of about 250 to 450 W.

In the invention, it is preferable that the ratio (Ws/Wb) of the RF electric power (Ws) for activating the oxygen-containing gas to the RF electric power (Wb) applied to the wafer is controlled to be a predetermined value or lower, for example, it is appropriate that the ratio is about 5 or less, about 4 or less, or in the range of about 0.22 to 4. From another viewpoint, it is preferable that the ratio Ws/Wb is set so that the change rate of the dielectric constant of the insulating film before and after ashing is about 10% or less, about 8% or less, or 5% or less.

It is preferable that an ashing time in the ashing method of the invention is set to such a degree that in the case where ashing of a resist is performed under the foregoing set conditions and the like, there are little ashing remains of the resist, and the resist is almost completely removed while overetching of the insulating film just under the resist is kept to a minimum. Specifically, about 1.5 to 5 minutes can be given as an example.

Incidentally, in the invention, it is preferable that the substrate is held by the lower electrode as described above, and it is preferable that the temperature of the lower electrode during the ashing is about 50° C. or lower, about 35° C. or lower, about 25° C. or lower, or about 20° C. or lower. Incidentally, with respect to the substrate temperature, for example, when the temperature of the lower electrode holding the substrate is set to the above temperature, the temperature of the substrate itself can be substantially set to a value in the neighborhood of the temperature.

Hereinafter, the ashing method of the present invention will be described on the basis of the drawings.

In the ashing method of this embodiment, the ashing apparatus shown in FIG. I was used. This ashing apparatus is mainly constituted by a vacuum chamber 5 provided with a plasma generating coil 1 on its outer circumference, a lower electrode 3 formed at a lower position in the vacuum chamber 5, a power source 2 for applying voltage to the plasma generating coil 1 and the vacuum chamber 5, a power source 6 for applying voltage to the lower electrode 3 and a chiller 7 for controlling the temperature of the lower electrode 3. A wafer 4 to be etched is held on the lower electrode 3.

An MSQ-HOSP (Hydride Organo Siloxane Polymer, dielectric constant: 2.5 to 2.7) film of a low dielectric constant film was formed by coating to a thickness of about 400 to 1000 nm as an interlayer insulating film on the semiconductor wafer, and a resist (for example, acetal resist) having a thickness of about 700 to 900 nm was coated thereon. An opening of a predetermined shape was formed in the resist, and a hole reaching the surface of the semiconductor wafer was formed in the interlayer insulating film by using this resist as a mask. The obtained semiconductor wafer was held on the lower electrode 3 of the foregoing ashing apparatus, and ashing of the resist on the wafer was performed.

The ashing was performed for about 2.5 minutes under the conditions that the temperature of the lower electrode (substrate) was 20° C., the mode was an RIE mode, the oxygen gas was introduced at 200 SCCM, the pressure was about 200 mT, the plasma generating RF power of the power source 2 was 1000 W and the RF power of the power source 6 for controlling ion drawing energy to the wafer was set to 200 W.

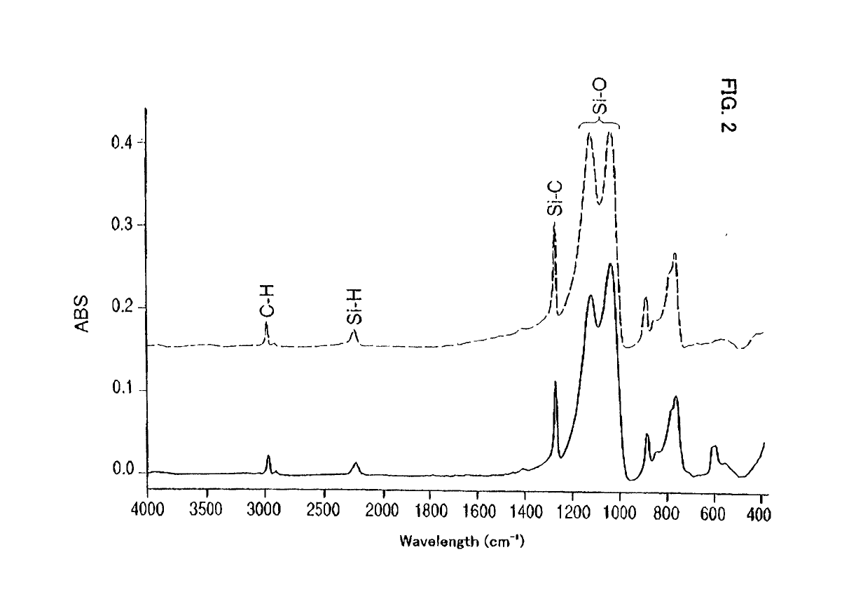

By such ashing, the Fourier transform infrared spectroscopy (FT-IR) waveform of the interlayer insulating film after the resist was almost completely removed was measured. The results are shown in FIG. 2 (thick line). The FT-IR waveform of the same interlayer insulating film before the ashing is performed is also shown in FIG. 2 (broken line).

According to FIG. 2, the waveform was hardly changed before and after the ashing, and a change in film quality was not recognized. That is, a decrease of a peak of a wavelength showing bonding to suppress dielectric constant, such as Si—H bonding, was not recognized, and an increase of a peak of a wavelength showing H—OH bonding to accelerate an increase of dielectric constant was also hardly recognized.

In other wards, oxygen ions can be easily drawn to the substrate by application of the RF electric power to the substrate, and by that, an SiO film is formed on the surface of the interlayer insulating film, and it is conceivable that this film functions as a protection film to suppress the change in the film quality of the interlayer insulating film.

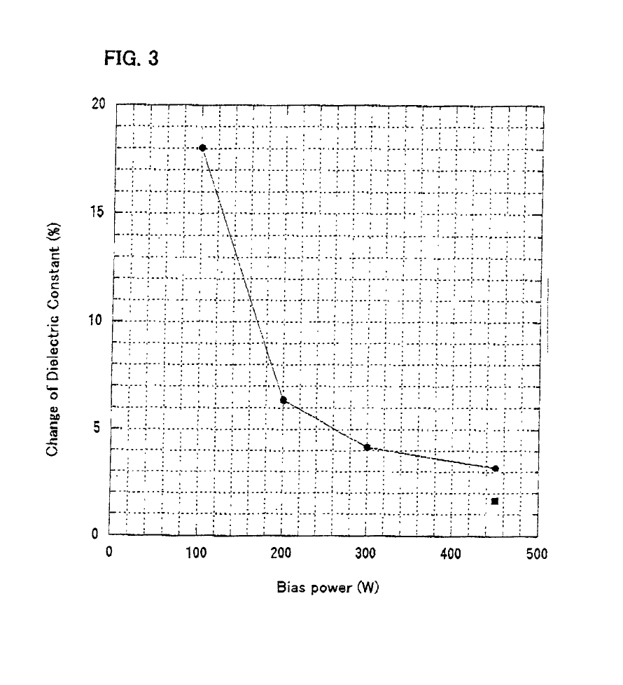

Besides, a change in the dielectric constant of the interlayer insulating film was measured in the case where the conditions were set to be the same as the above except that the temperature of the lower electrode was 20° C., the plasma generating RF power of the power source 2 was 1000 W or 100 W, and the RF power of the power source 6 for controlling the ion drawing energy to the wafer was 100 to 450 W. The results are shown in FIG. 3. In FIG. 3, a black dot indicates a result when the plasma generating RF power of the power source 2 was 1000 W, and a black square indicates a result when it was 100 W.

According to FIG. 3, in the case where the RF electric power applied to activate the gas introduced in the chamber is 1000 W, the change rate of the dielectric constant of the insulating film before and after the ashing can be made about 10% or less when the RF electric power applied to the side of the substrate is made about 150 W or higher, the change rate can be made about 8% or less when the RF electric power is made about 190 W or higher, and the change rate can be made about 5% or less when the RF electric power is made about 250 W or higher.

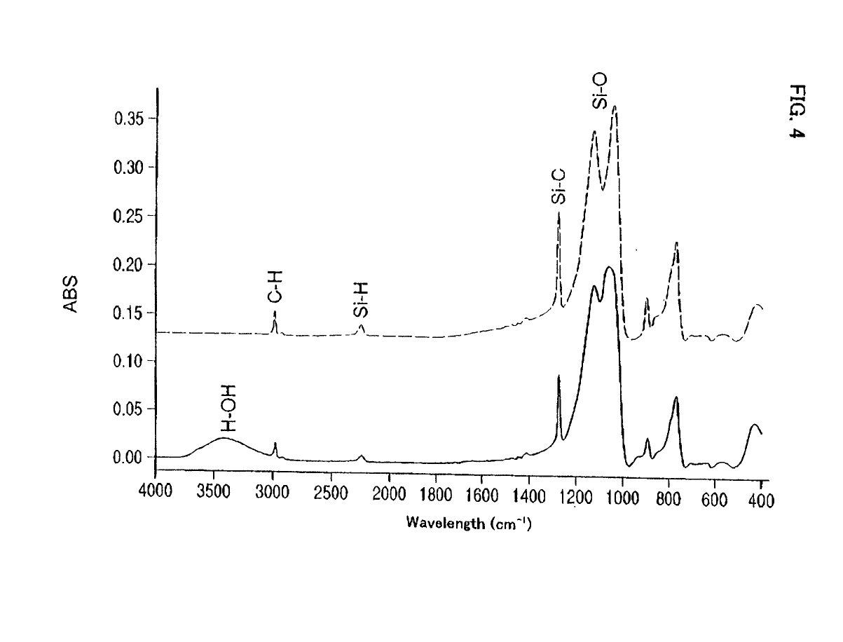

For comparison, the FT-IR waveform was measured in the case where the temperature of the lower electrode was made 20° C., the mode of ashing was the RIE mode, the plasma generating RF power of the power source 2 was set to 1000 W, and the RF power of the power source 6 for controlling the ion drawing energy to the wafer was not applied. The results are shown in FIG. 4 (thick line). The FT-IR waveform of the same interlayer insulating film before the ashing is performed is also shown in FIG. 4 (broken line).

According to FIG. 4, by lowering the temperature of the lower electrode to 20° C., as described later, the intensity 0.0349 of H—OH bonding generated by the ashing at a high temperature of 250° C. and appearing near a wavelength of 3500 Å can be reduced to 0.0222, that is, about two-thirds, and an increase of the dielectric constant can be suppressed.

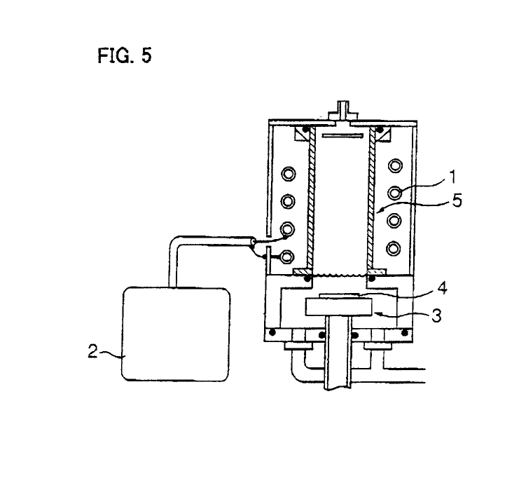

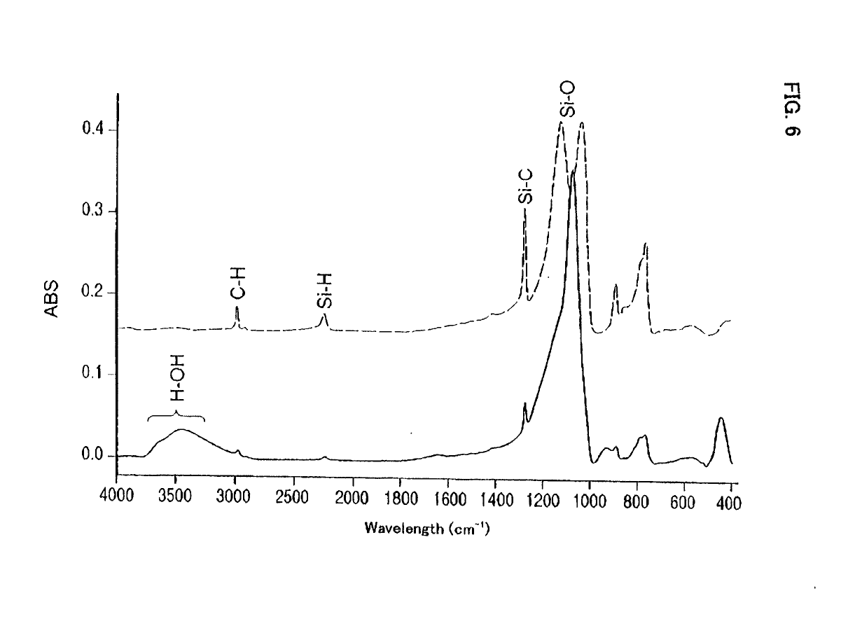

On the other hand, as shown in FIG. 5, a down flow type ashing apparatus which is constituted by a vacuum chamber 5 provided with a plasma generating coil 1 on its outer circumference, a lower electrode 3 formed at a lower position in the vacuum chamber 5, a power source 2 for applying voltage to the plasma generating coil 1 and the vacuum chamber 5 and a chiller for controlling the temperature of the lower electrode 3, and which is not provided with a power source for applying voltage to the lower electrode 3, was used, and an interlayer insulating film similar to the above was subjected to ashing under the conditions that the temperature of the lower electrode was 250° C. and the plasma generating RF power of the power source 2 was set to 1000 W. The FT-IR waveform of the interlayer insulating film after the resist was almost completely removed by this ashing was measured. The results are shown in FIG. 6 (thick line). The FT-IR waveform of the same interlayer insulating film before the ashing treatment is performed is also shown in FIG. 6 (broken line).

According to FIG. 6, in the waveform before the treatment, although C—H bonding concerned in the lowering of the dielectric constant appears near the wavelength of 3000 Å, Si—H bonding appears near 2300 Å and Si—C bonding appears near 1300 Å, all of those wavelengths are decreased after the treatment, and on the other hand, H—OH bonding concerned in the increase of the dielectric constant appears near 3500 Å remarkably. It is understood that the film quality is changed. It is conceivable that this is because the RF electric power was not capable of being independently applied to the lower electrode, so that the ion energy necessary for suppressing the increase of the dielectric constant was not capable of being controlled.

According to the invention, a substrate having a resist mask formed through an insulating film is held in a chamber of an ashing apparatus, RF electric power is applied to activate a gas containing oxygen atoms introduced in the chamber, and RF electric power is applied to the side of the substrate to perform ashing of the resist mask, so that an increase in the dielectric constant of the insulating film caused by the ashing can be suppressed, a signal delay by an increase in capacitance between wiring lines can be suppressed. Therefore, device performance can be improved.

Especially, the RF electric power (Wb) applied to the side of the substrate is controlled to be a definite value or higher, or the ratio (Ws/Wb) of the RF electric power (Ws) for activating the oxygen-containing gas to the RF electric power (Wb) applied to the side of the substrate is controlled to be a definite value or lower, further the substrate is held on the electrode and this electrode is set to about 20° C. or lower, so that the increase in the dielectric constant of the insulating film caused by ashing can be more effectively suppressed. Thus, for example, in a semiconductor device adopting a low dielectric constant film as an insulating film, it becomes possible to prevent the change in the film quality of the insulating film caused by ashing of a mask resist after a hole etching at a hole or damascene trench step or after groove working of a damascene trench, and to reduce the change in the dielectric constant of the insulating film.

What is claimed is:

1. An ashing method comprising the steps of:
holding a substrate having a resist mask formed through an insulating film in a chamber of an ashing apparatus; and
applying an RF electric power to activate an oxygen-containing gas introduced in the chamber in order to perform ashing of the resist mask, while an RF electric power is applied to the substrate.

2. The ashing method according to claim 1, wherein the RF electric power (Wb) applied to the substrate is controlled to be a predetermined value or higher.

3. The ashing method according to claim 2, wherein the RF electric power (Wb) is 150 W or higher.

4. The ashing method according to claim 1, wherein the RF electric power (Ws) for activating the oxygen-containing gas is 1000 W or less.

5. The ashing method according to claim 1, wherein a ratio (Ws/Wb) of the RF electric power (Ws) for activating the oxygen-containing gas to the RF electric power (Wb) applied to the substrate is controlled to be a predetermined value or lower.

6. The ashing method according to claim 5, wherein the ratio (Ws/Wb) is 5 or less.

7. The ashing method according to claim 1, wherein the ratio (Ws/Wb) is set so that the change rate of the dielectric constant of the insulating film before and after ashing is 10%.

8. The ashing method according to claim 1, wherein the substrate is set to a temperature of about 20° C. or lower.

9. The ashing method according to claim 1, wherein the insulating film formed on the substrate is a low dielectric constant film having a dielectric constant of 3.5 or less.

10. The ashing method according to claim 1, wherein the RF electric power applied for activation of the oxygen-containing gas is supplied by a first power source and the RF electric power applied to the substrate is supplied by a second power source via a lower electrode formed in the chamber.

11. The ashing method according to claim 10, wherein the lower electrode supports the substrate and is controlled to have a predetermined temperature for maintaining the temperature of the substrate.

12. The ashing method according to claim 1, wherein the oxygen-containing gas is an oxygen gas, an ozone gas, a mixture thereof, or a mixture of either or both of these gases with a N₂ gas or a CF₄ gas.
